(19) United States
(12) Patent Application Publication
(10) Pub. No.: US 2010/0248163 A1
(43) Pub. Date: Sep. 30, 2010

(54) PATTERN FORMATION METHOD

(76) Inventor: Shinichi ITO, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/728,707

(22) Filed: Mar. 22, 2010

(30) Foreign Application Priority Data
Mar. 26, 2009 (JP) 2009-077257

(51) Int. Cl. G03F 7/20

(52) U.S. Cl. 430/325

(57) ABSTRACT

A pattern formation method, includes: bringing a template into contact with a photo-curable agent to fill the photo-curable agent into a concave pattern formed on the template; forming a hydrophilizing component in the photo-curable agent to hydrophilize the photo-curable agent; irradiating the filled photo-curable agent with a first light to cure the photo-curable agent; irradiating the photo-curable agent including the hydrophilizing component with a second light after irradiating with the first light to cause a reaction of the photo-curable agent at an interface of the template; and demolding the template from the photo-curable agent to form a photo-curable agent pattern.

### CROSS-REFERENCE TO RELATED APPLICATIONS

This application is based upon and claims the benefit of priority from the prior Japanese Patent Application No. 2009-077257, filed on Mar. 26, 2009; the entire contents of which are incorporated herein by reference.

### BACKGROUND

1. Field

Embodiments of this invention relate generally to a pattern formation method.

2. Background Art

When forming fine patterns by optical nanoimprint methods, patterns having high aspect ratios unfortunately incur resist pattern breaks during a mold release process. To solve such problems, methods have been discussed (for example, refer to JP-A 2008-91782 (Kokai)) to use a material including a UV light-absorbing functional group for patterning to cause a volumetric contraction of the pattern during UV light irradiation and reduce wear during demolding.

However, it is difficult to obtain patterns having perpendicular side walls with such a method in the case where patterns have trapezoidal configurations and the like after the contraction.

### SUMMARY

According to an aspect of the invention, there is provided a pattern formation method, including: bringing a template into contact with a photo-curable agent to fill the photo-curable agent into a concave pattern formed on the template; forming a hydrophilizing component to an interface between a the photo-curable agent and a pattern surface of the template; irradiating the filled photo-curable agent with a first light to cure the photo-curable agent; irradiating the photo-curable agent including the hydrophilizing component with a second light after irradiating with the first light to cause a reaction of the photo-curable agent at an interface of the template; and demolding the template from the photo-curable agent to form a photo-curable agent pattern.

### BRIEF DESCRIPTION OF THE DRAWINGS

FIG. 1 is a schematic view of a imprinting apparatus used to implement a pattern formation method according to a first embodiment;

FIG. 2 is a flowchart illustrating the pattern formation method according to the first embodiment;

FIGS. 3A to 3F are cross-sectional views of processes, illustrating the pattern formation method according to the first embodiment;

FIG. 4 is a flowchart illustrating a pattern formation method according to a second embodiment;

FIGS. 5A and 5B are cross-sectional views of processes, illustrating the pattern formation method according to the second embodiment;

FIG. 6 is a flowchart illustrating a pattern formation method according to a third embodiment;

FIGS. 7A and 7B are cross-sectional views of processes, illustrating the pattern formation method according to the third embodiment;

FIG. 8 is a flowchart illustrating a pattern formation method according to a fourth embodiment;

FIGS. 9A and 9B are cross-sectional views of processes, illustrating the pattern formation method according to the fourth embodiment;

FIG. 10 is a schematic view of a imprinting apparatus used to implement a pattern formation method according to a fifth embodiment;

FIG. 11 is a flowchart illustrating a pattern formation method according to the fifth embodiment;

FIGS. 12A to 12C are cross-sectional views of processes, illustrating the pattern formation method according to the fifth embodiment; and

FIG. 13 is a cross-section schematic view of another available template for the pattern formation method according to each of the embodiments.

### DETAILED DESCRIPTION

Embodiments of the invention will now be described with reference to the drawings.

### First Embodiment

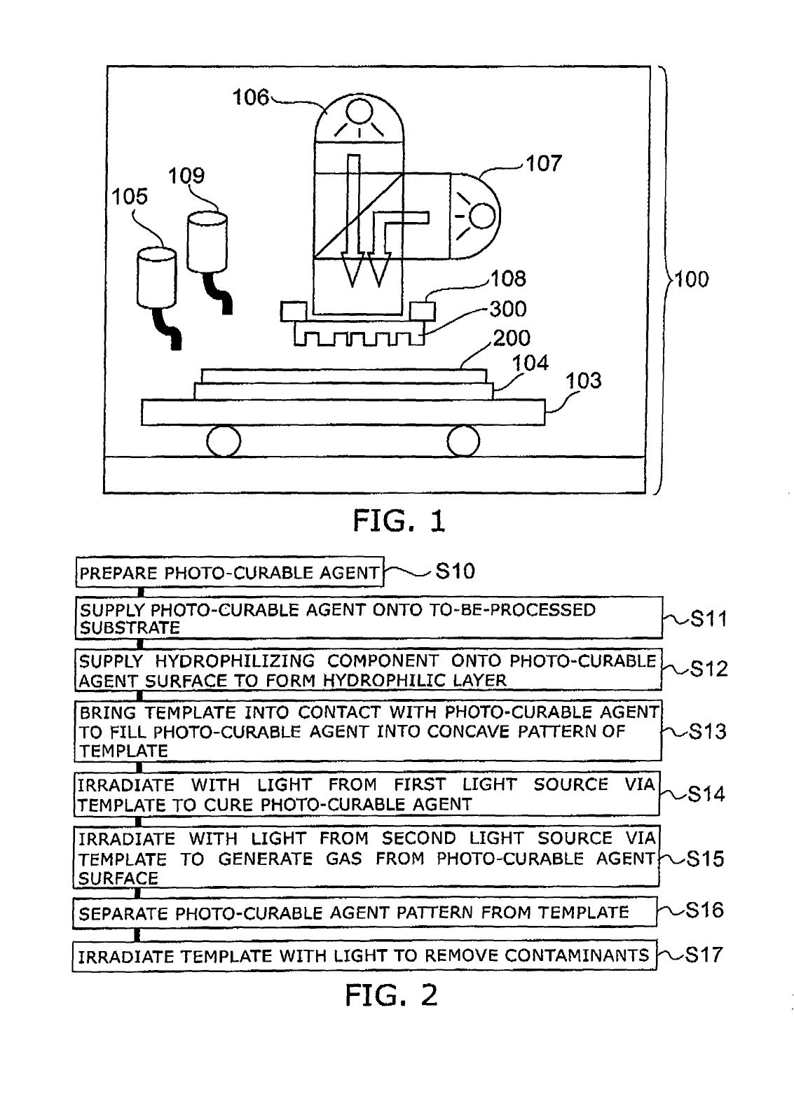

A pattern formation method according to an imprinting method according to a first embodiment will now be described using FIG. 1 to FIG. 3F.

First, a schematic of an imprinting apparatus using the pattern formation method according to this embodiment will be described. FIG. 1 is a schematic configuration diagram of the imprinting apparatus using the pattern formation method according to this embodiment.

An imprinting apparatus 100 includes: a chuck for the to-be-processed substrate 104 that fixes a to-be-processed substrate 200 with a major surface (pattern formation surface) of the to-be-processed substrate 200 facing upward; a processing stage 103 for moving the chuck for the to-be-processed substrate 104 three dimensionally; a photo-curable agent coating unit 105 that selectively supplies a photo-curable agent onto the to-be-processed substrate 200; a template holding unit 108 that holds a template 300 for imprinting, where a concave pattern is formed on the template 300 and the template 300 is held with the concave pattern formation surface facing downward; a first light source (e.g., a UV lamp) 106 that radiates light via the template 300 to cure the photo-curable agent; a second light source 107 that radiates to promote to-be-processed substrate of a photo-curable agent pattern cured by the light irradiation from the first light source 106; and a high humidity supply unit 109 that supplies a hydrophilizing component for hydrophilizing the photo-curable agent to the to-be-processed substrate surface (the concave pattern formation surface). A light source having a wavelength λ, for example, less than 200 nm may be used as the second light source. In this embodiment, a Xe2 excimer lamp with λ=172 nm is used. The template 300 for the imprinting is a template including a concave pattern made on a transparent quartz substrate by plasma etching and the like. The high humidity supply unit 109 may be included in the apparatus 100 as illustrated in FIG. 1 or may be provided as a unit external to the apparatus 100. The to-be-processed substrate 200 and the template 300 are set in the apparatus interior when utilizing the apparatus 100 of FIG. 1 and are not included in the configuration of the apparatus 100.

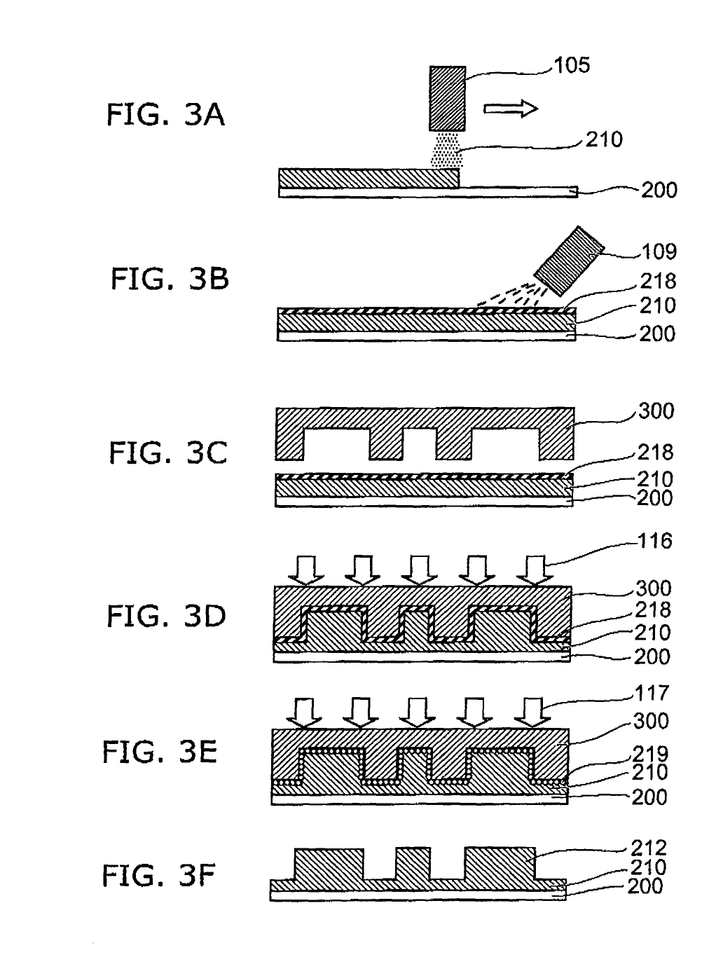

The pattern formation method using the imprinting apparatus described above will now be described with reference to FIG. 2 to FIG. 3F. FIG. 2 is a flowchart illustrating the pattern formation method according to this embodiment.

FIGS. 3A to 3F are cross-sectional views of processes, illustrating the pattern formation method according to this embodiment.

First, a photo-curable agent, e.g., an epoxy resin, to be used for the pattern formation according to this embodiment was prepared (step S10). However, resins that can be used as the photo-curable agent are not limited thereto. Any photo-curable material generally used in imprinting methods such as acrylic polymers may be used.

Then, as illustrated in FIG. 3A, after fixing the to-be-processed substrate 200 by the chuck for the to-be-processed substrate 104 with the major surface of the to-be-processed substrate 200 facing upward, the to-be-processed substrate 200 was moved directly below the photo-curable agent coating unit 105; and a photo-curable agent 210 was coated and formed onto a pattern formation region of the major surface of the to-be-processed substrate 200 (step S11). The coating of the photo-curable agent 210 was performed by scanning the photo-curable agent coating unit 105. In this embodiment, the photo-curable agent 210 is selectively coated onto the to-be-processed substrate 200.

Continuing as illustrated in FIG. 3B, a hydrophilic component, e.g., moisture, to hydrophilize the photo-curable agent 210 was adsorbed to the coated film surface of the photo-curable agent using the high humidity supply unit 109 to form a hydrophilic layer 218 (step S12). Although water is favorable as a hydrophilizing component adsorbed to the photo-curable agent surface, alcohols such as butanol, heptanol, hexanol, and octanol may be supplied and adsorbed; also, water may be supplied and adsorbed after mixing with such alcohols. Here, to increase the dimensional controllability, it is favorable to form the hydrophilic layer 218 as thin as possible with a film thickness on the curable agent surface of about 1 nm or less. To this end, it is favorable to provide a vapor producing unit in the high humidity supply unit 109 to supply the hydrophilizing component using a vapor.

However, as long as the hydrophilic layer 218 can be formed with the desired thickness precision, the high humidity supply unit 109 may be used to supply the hydrophilizing component using a mist or by coating.

Then, as illustrated in FIG. 3C, the substrate 200 on which the hydrophilic layer 218 was formed was moved directly below the template 300 held by the template holding unit using the to-be-processed substrate stage.

Continuing as illustrated in FIG. 3D, the stage for the to-be-processed substrate 103 was moved upward to bring the concave pattern surface of the template 300 into contact with the hydrophilic layer 218 of the photo-curable agent surface layer formed on the to-be-processed substrate 200 (step S13). At this time, the photo-curable agent 210 has fluidity and therefore is filled into the concave pattern of the template by a capillary action to form the hydrophilic layer 218 of the photo-curable agent at the interface between the photo-curable agent 210 and the pattern surface of the template 300.

Here, in the case where the patterned template 300 is synthetic quartz, the capillary action of the hydrophilic layer 218 of the photo-curable agent surface is efficient and can suppress filling defects. Although generally the relationship among a height h and a contact angle θ (in this embodiment, the contact angle between the template and the resist surface layer) of a liquid having a surface tension γ and a viscosity ρ rising into a capillary having a radius r is expressed by γ cos θ=ρgrh/2, it is desirable to reduce cos θ to increase the fillability, i.e., the height h. In this embodiment, the fillability can be increased because the contact angle θ between the synthetic quartz and the hydrophilic layer is small. Herein, “filling defect” refers to cases such as where the photo-curable agent is not sufficiently filled into the pattern and as a result a photo-curable agent pattern of the desired dimensions and the desired configuration is not formed.

After filling the photo-curable agent 210, the positions of the to-be-processed substrate major surface and the template pattern are aligned; and subsequently, a light irradiation 116 (a first light irradiation) is performed with the first light source from a surface opposing the concave-convex pattern surface of the template 300 to cure the photo-curable agent (step S14). A lamp emitting light having a wavelength in the range of 300 nm to 400 nm was used as the light source 106. It is sufficient that the wavelength of the light source used in this process includes a wavelength such that the photo-curable agent absorbs light to cause a photo crosslinking reaction. A high pressure mercury lamp, tungsten lamp, UV-LED, ultraviolet laser, etc., may be selected according to the absorption band of the photo-curable agent.

Then, as illustrated in FIG. 3E, the hydrophilic layer 218 of the photo-curable agent 210 was irradiated (a second light irradiation 117) with Xe excimer lamp light having a wavelength of 172 nm from the surface opposing the concave-convex pattern surface of the template 300 using the second light source; the photo-curable agent 210 of the template 300 interface was decomposed; and a gas 219 was generated (step S15). The light used in this process may have any wavelength that excites the hydrophilizing component in the hydrophilic layer of the photo-curable agent surface to promote the decomposition reaction of the photo-curable agent. In the case where the hydrophilizing component was water, light of 200 nm or less was absorbed to generate OH radicals or oxygen radicals; these radicals reacted with the photo-curable agent; and carbon dioxide gas was generated. In the case where hydrophilizing components (e.g., aqueous hydrogen peroxide or alcohols) having an absorption band near a wavelength of 220 nm are used, the decomposition reaction of the photo-curable agent can be promoted to generate a gas even when a KrCl excimer lamp having a wavelength of 222 nm is used. In the case where hydrophilizing components (e.g., water or alcohols) having an absorption band near a wavelength of 190 nm are used, the decomposition reaction of the photo-curable agent can be promoted to generate a gas even when an ArF excimer laser having a wavelength of 193 nm is used.

Although it is sufficient that the light irradiation performed in this process is enough to generate the gas 219 for improving the demolding characteristics of the template, the demolding may be performed while further curing the photo-curable agent by light irradiation to make the pattern dimensions narrower. In such a case, the irradiation amount to provide the desired dimensions of the photo-curable agent pattern after the demolding may be determined beforehand; and control of the irradiation amount may be performed according to the set dimensions.

After generating the gas at the interface between the pattern surface of the template and the photo-curable agent, as illustrated in FIG. 3F, the to-be-processed substrate stage was moved downward; the to-be-processed substrate 200 and the photo-curable agent 210 were demolded from the template 300; and a photo-curable agent pattern 212 was formed on the to-be-processed substrate (step S16). It is also possible to demold from the template 300 during the gas generation process by the light irradiation illustrated in FIG. 3E.

According to the pattern formation method according to this embodiment, the photo-curable agent surface is hydrophilized and brought into contact with the pattern surface of the template. Therefore, filling defects of the curable agent into the template pattern can be suppressed; and the filling characteristics can be improved. Also, a gas is generated at the interface between the template and the curable agent prior to or during demolding of the template and the curable agent. Thereby, the demolding thereof is promoted; and the demolding characteristics can be improved.

Organic contaminants adhered to the template surface may be decomposed and removed by appropriately irradiating the template with the second light source after the demolding (step S17). Further, such an organic contaminant removal process may be performed simultaneously to the demolding process illustrated in step S16; and the demolding may be performed while irradiating with the excimer lamp light 117. Thereby, organic contaminants of the template surface may be decomposed by excimer lamp light irradiation during demolding.

### Second Embodiment

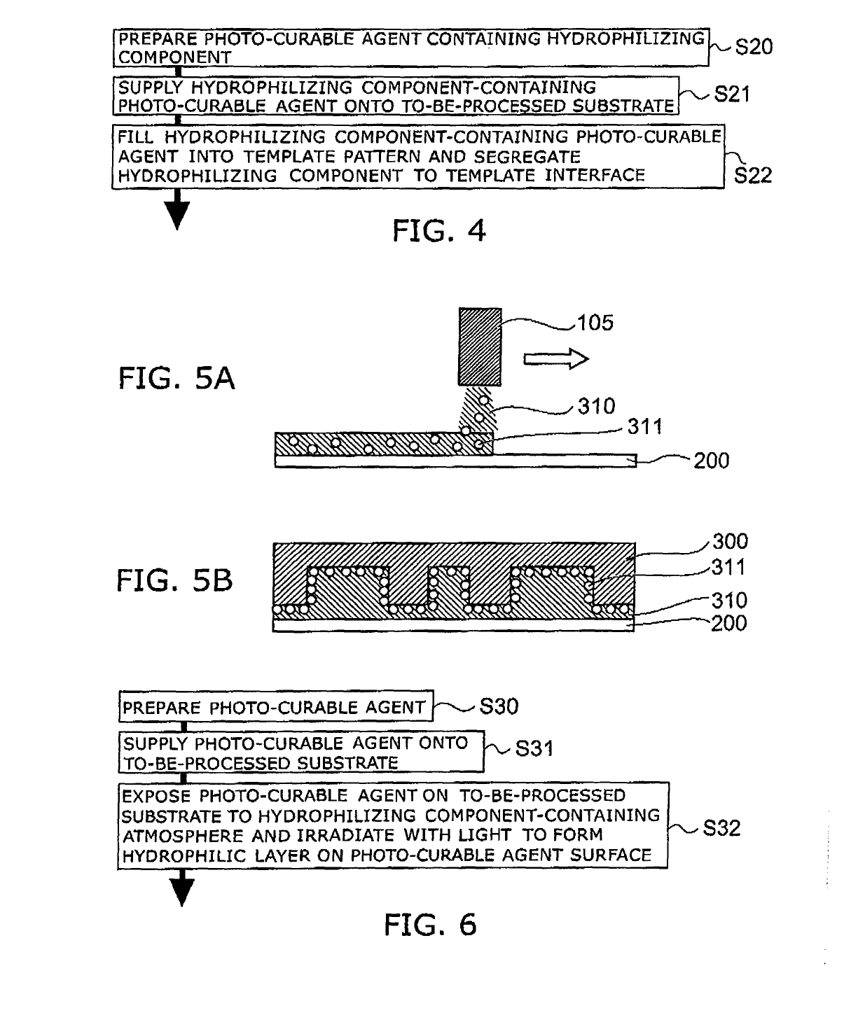

A pattern formation method according to a second embodiment will now be described with reference to FIG. 4 to FIG. 5B. FIG. 4 is a flowchart illustrating the pattern formation method according to this embodiment. FIGS. 5A and 5B are cross-sectional views of processes, illustrating the pattern formation method according to this embodiment. In the description of the pattern formation method according to this embodiment, portions of the descriptions and the drawings used in the descriptions of processes similar to those of the pattern formation method according to the first embodiment are omitted; and like reference numerals are used in the drawings.

First, a photo-curable agent containing a hydrophilizing component to hydrophilize the photo-curable agent, e.g., an epoxy resin and the like, was prepared (step S20). Moisture was used as the hydrophilizing component. An epoxy resin containing moisture of about 1 wt % was prepared as the photo-curable agent. Alcohols such as butanol, heptanol, hexanol, and octanol may be used as the hydrophilizing component. Resins that can be utilized as the photo-curable agent are not limited to epoxy resins. Any material generally used for imprinting such as hydrophilizing component that contains acrylic polymers may be used.

Then, as illustrated in FIG. 5A, after fixing the to-be-processed substrate 200 by a to-be-processed substrate chuck with the major surface of the to-be-processed substrate 200 facing upward, the to-be-processed substrate 200 was moved directly below the photo-curable agent coating unit 105; a fluid photo-curable agent 310 containing a hydrophilizing component 311 was coated onto the pattern formation surface of the to-be-processed substrate 200 to form a film. The coating of the photo-curable agent 310 was performed by scanning the photo-curable agent coating unit 105 (step S21).

Continuing as illustrated in FIG. 5B, after completing the coating of the curable agent 310, the to-be-processed substrate 200 was moved directly below the template 300 using the stage for the to-be-processed substrate. The template 300 was brought into contact with the curable agent 310; and the curable agent 310 was filled into the concave pattern of the template (step S22). At this time, the hydrophilizing component 311 included in the hydrophilizing component containing epoxy resin segregates to the interface of the template and the resin; and the fluid photo-curable agent 310 is filled into the concave regions of the template by capillary action.

The subsequent pattern formation processes are similar to some of the processes of the first embodiment. Namely, as illustrated in steps S14 to S17 and FIGS. 3D to 3F, the light irradiation process to cure the photo-curable agent, the light irradiation process to generate a gas by causing a decomposition reaction of the curable agent by exciting the hydrophilizing component, and a demolding process of the template are implemented; and a pattern is formed on the to-be-processed substrate.

In this embodiment, a hydrophilic layer may be formed in the photo-curable agent surface layer by a method similar to that of the first embodiment after coating the photo-curable agent containing the hydrophilizing component; and after forming the hydrophilic layer, the processes illustrated in FIGS. 3B to 3F of the first embodiment may be implemented.

### Third Embodiment

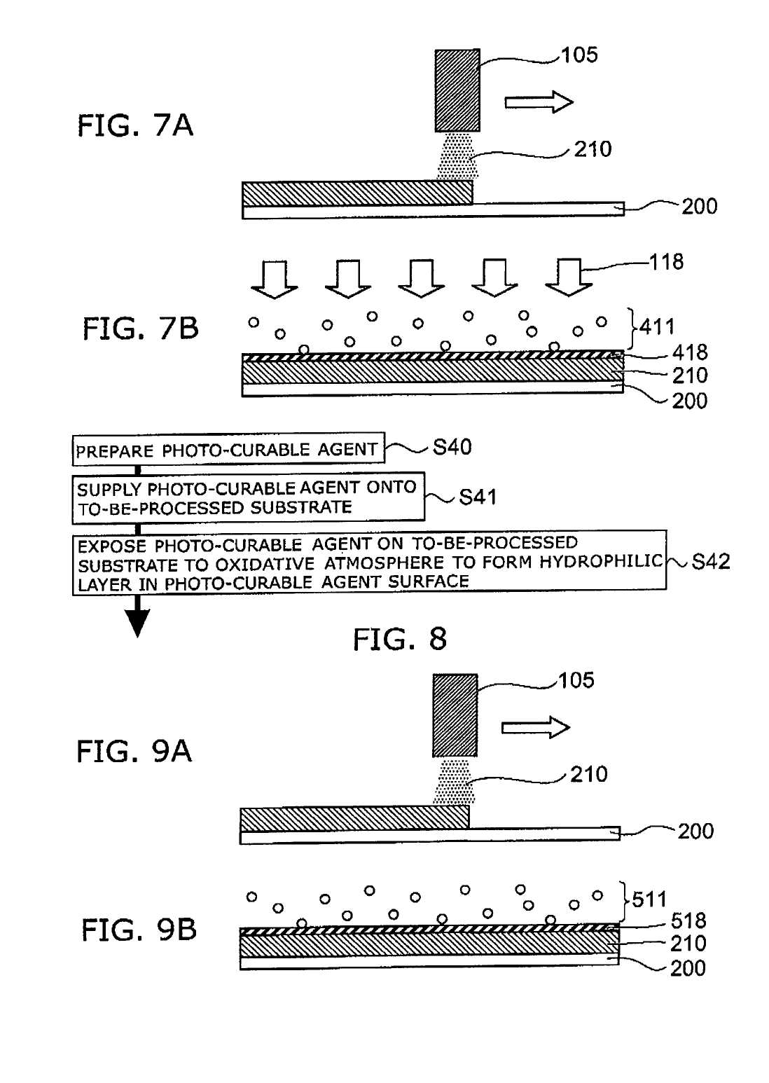

A pattern formation method according to a third embodiment will now be described with reference to FIG. 6 to FIG. 7B. FIG. 6 is a flowchart illustrating the pattern formation method according to this embodiment. FIGS. 7A and 7B are cross-sectional views of processes, illustrating the pattern formation method according to this embodiment. In the description of the pattern formation method according to this embodiment, portions of the descriptions and the drawings used in the descriptions of processes similar to those of the pattern formation method according to the first embodiment are omitted; and like reference numerals are used in the drawings.

First, the photo-curable agent 210 to be used in the pattern formation method according to this embodiment was prepared (step S30). A material similar to that of the first embodiment or the second embodiment may be used as the photo-curable agent 210.

Then, as illustrated in FIG. 7A, the fluid photo-curable agent 210 was coated and formed onto the pattern formation surface of the to-be-processed substrate 200 using the photo-curable agent coating unit 105 (step S31) similarly to the first embodiment. The coating of the photo-curable agent was performed by scanning the photo-curable agent coating unit.

Continuing as illustrated in FIG. 7B, with light irradiation, the photo-curable agent 210 was exposed to the atmosphere with hydrophilizing component 411, e.g. an atmosphere with moisture; the photo-curable agent 210 was irradiated with Xe excimer lamp light 118 having a wavelength of 172 nm; and a hydrophilic layer 418 was formed on the surface of the photo-curable agent (step S32). In this hydrophilic reaction, moisture in the atmosphere is excited by absorbing light having a wavelength of 200 nm or less; OH radicals are generated; the OH radicals react with the photo-curable agent; OH is generated in the photo-curable agent; and the photo-curable agent becomes hydrophilicity. In the case where the pattern formation method according to this embodiment is implemented using the imprinting apparatus illustrated in FIG. 1, it is possible to irradiate using the second light source 107. However, light irradiation is also possible using another light source different from the first light source and the second light source.

In this light irradiation process, the curable agent is maintained in an uncured state enough to be fillable during the subsequent filling process of the curable agent into the template pattern. Therefore, light is radiated with an irradiation amount such that the curing reaction of the irradiation process does not progress too much. Further, in this irradiation process, the light is radiated with an irradiation amount low enough that the reaction of the photo-curable agent in this irradiation process does not prevent photo-curing effects from occurring in the curable agent by the light irradiation of the subsequent curing process of the curable agent filled into the template pattern.

It is also possible to form a hydrophilic layer on the photo-curable agent surface by irradiating the curable agent with light in a state in which the to-be-processed substrate and the photo-curable agent are exposed to the atmosphere with oxygen (the atmosphere with hydrophilizing component 411) instead of or in addition to the moisture described above. Similarly to the hydrophilizing process illustrated in FIG. 7B described above, a hydrophilic layer is formed on the photo-curable agent surface in an atmosphere containing oxygen by exciting oxygen by irradiating with light having a wavelength absorbed by oxygen of 200 nm or less to generate oxygen radicals and cause a photocuring effect. As described above, this irradiation process may be implemented by a light irradiation using the second light source 107 of the apparatus 100 illustrated in FIG. 1.

In this irradiation process, the light irradiation is performed at an irradiation amount such that the curing reaction of the photo-curable agent does not progress too much and at an irradiation amount such that the photo-curable agent does not react to oxidatively decompose more than necessary.

It is also possible to form a hydrophilic layer on the photo-curable agent surface by irradiating the to-be-processed substrate with light in a state in which the to-be-processed substrate is exposed to the atmosphere with a hydrogen peroxide or ozone (the atmosphere with the hydrophilizing component 411) instead of or in addition to the moisture or oxygen. A hydrophilic layer may be formed on the photo-curable agent surface also in an atmosphere that includes hydrogen peroxide by exciting by irradiating with light having a wavelength absorbed by hydrogen peroxide of 250 nm or less to generate OH radicals and cause an effect on the coated photo-curable agent surface. A hydrophilic layer may be formed on the photo-curable agent surface also in an atmosphere that includes ozone by exciting by irradiating with light having a wavelength absorbed by ozone of 300 nm or less to generate oxygen radicals and cause an effect on the coated photo-curable agent surface. As described above, the light irradiation may be implemented using the second light source 107 of the imprinting apparatus 100 illustrated in FIG. 1. The irradiation amount in such a case is such that the curing reaction of the photo-curable agent does not progress too much.

The subsequent pattern formation processes are similar to some of the processes of the first embodiment. Namely, as illustrated in steps S13 to S17 and FIGS. 3C to 3F, the filling process bringing the template into contact with the photo-curable agent to fill the photo-curable agent into the concave pattern of the template (at this time, the hydrophilic layer may be formed at the template interface as illustrated in FIG. 3D), the light irradiation process to cure the photo-curable agent, the light irradiation process to cause a decomposition reaction of the curable agent to generate a gas by exciting the hydrophilizing component, and the demolding process of the template may be implemented to form the pattern on the to-be-processed substrate.

It is also possible to add the processes illustrated in FIGS. 3B to 3F of the first embodiment after the hydrophilizing process of the photo-curable agent surface illustrated in FIG. 7B. In other words, after hydrophilizing the photo-curable agent surface by light irradiation in a hydrophilizing component-containing atmosphere, a hydrophilic component may be adsorbed to the photo-curable agent surface using the high humidity supply unit 109 illustrated in FIG. 3B and the like. Subsequently, by implementing the processes illustrated in FIGS. 3C to 3F, the pattern can be formed onto the to-be-processed substrate. In this embodiment, it is also possible to use a photo-curable agent containing a hydrophilizing component such as that used in the pattern formation method of the second embodiment as the curable agent. A segregation layer of the hydrophilizing component may be formed at the interface between the template and the curable agent.

### Fourth Embodiment

A pattern formation method according to a fourth embodiment of the invention will now be described with reference to FIG. 8 to FIG. 95. FIG. 8 is a flowchart illustrating the pattern formation method according to this embodiment. FIGS. 9A and 9B are cross-sectional views of processes, illustrating the pattern formation method according to this embodiment. In the description of the pattern formation method according to this embodiment, portions of the descriptions and the drawings used in the descriptions of processes similar to those of the pattern formation method according to the first embodiment are omitted; and like reference numerals are used in the drawings.

First, the photo-curable agent 210 to be used in the pattern formation method according to this embodiment was prepared (step S40). A material similar to the photo-curable agent of any of the first embodiment to the third embodiment may be used as the photo-curable agent 210.

Then, as illustrated in FIG. 9A, the fluid photo-curable agent 210 was coated and formed onto the pattern formation surface of the to-be-processed substrate 200 using the photo-curable agent coating unit 105 (step S41) similarly to the first embodiment. The coating of the photo-curable agent was performed by scanning the photo-curable agent coating unit.

Continuing as illustrated in FIG. 9B, the photo-curable agent 210 was exposed to an atmosphere that contains an oxidative component that oxidizes the photo-curable agent to form a hydrophilic layer on the photo-curable agent surface (step S42). For example, the oxidizing atmosphere 511 contains ozone, hydrogen peroxide, or nitrogen peroxide or a gas atmosphere of a mixture thereof.

It is sufficient that the concentration and the exposure time of the oxidative component of the atmosphere are low enough that the photo-curable agent does not react such that the photo-curable agent is oxidatively decomposed more than necessary or the curable agent can no longer be cured in the subsequent photocuring process of the curable agent while being enough to hydrophilize the surface.

It is also possible to form a hydrophilic layer including a hydrophilizing component on the photo-curable agent surface by irradiating the photo-curable agent with light having a wavelength absorbed by the oxidative component via the oxidative component-containing atmosphere 511 to optically excite the oxidative component in a state in which the photo-curable agent is exposed to the atmosphere 511 that contains oxidative component. This irradiation process may be implemented using, for example, the second light source of the apparatus 100 illustrated in the first embodiment.

The subsequent pattern formation processes are similar to some of the processes of the first embodiment. Namely, as illustrated in steps S13 to S17 and FIGS. 3C to 3F, the filling process bringing the template into contact with the photo-curable agent to fill the photo-curable agent into the concave pattern of the template (at this time, the hydrophilic layer is formed at the template interface as illustrated in FIG. 3D), the light irradiation process to cure the photo-curable agent, the light irradiation process to cause a decomposition reaction of the curable agent to generate a gas by exciting the hydrophilic layer, and the to-be-processed substrate process of the template may be implemented to form the pattern on the to-be-processed substrate.

It is also possible to add the processes illustrated in FIGS. 3B to 3F of the first embodiment after the hydrophilizing process of the photo-curable agent surface illustrated in FIG. 9B. In other words, after hydrophilizing the photo-curable agent surface by exposing to the atmosphere that contains an oxidative component, a hydrophilic component may be adsorbed to the photo-curable agent surface using the high humidity supply unit 109 illustrated in FIG. 3B and the like. Subsequently, by implementing the processes illustrated in FIGS. 3C to 3F, the pattern can be formed onto the to-be-processed substrate. In this embodiment, it is also possible to use a photo-curable agent containing a hydrophilizing component such as that used in the pattern formation method of the second embodiment as the curable agent. A segregation layer of the hydrophilizing component may be formed at the interface between the template and the curable agent.

### Fifth Embodiment

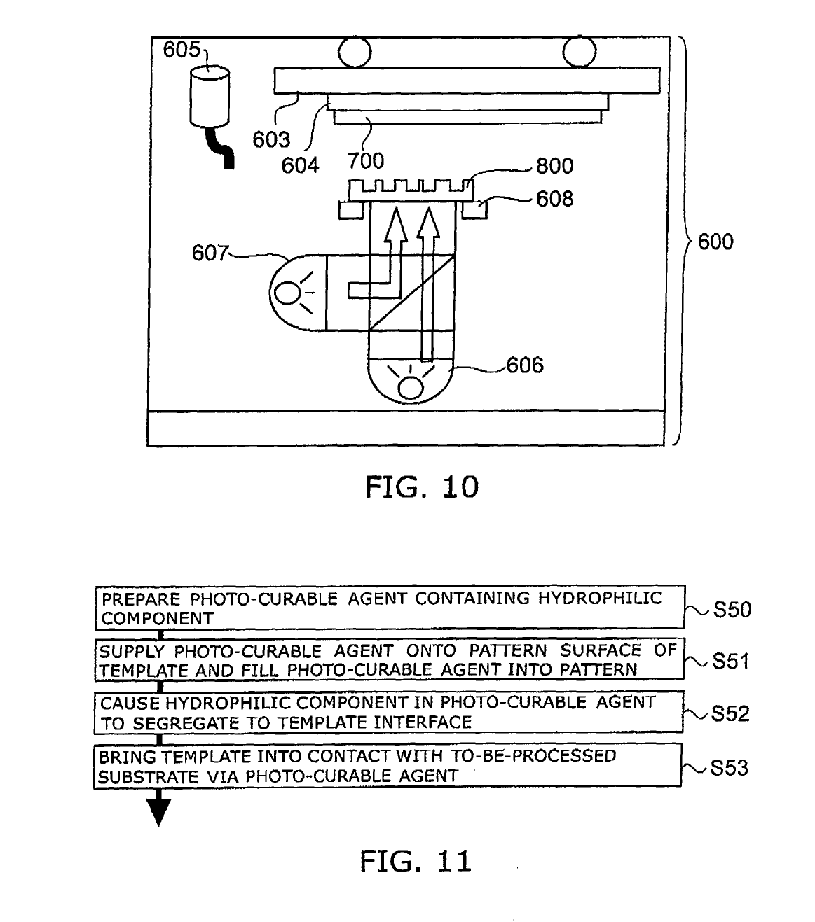

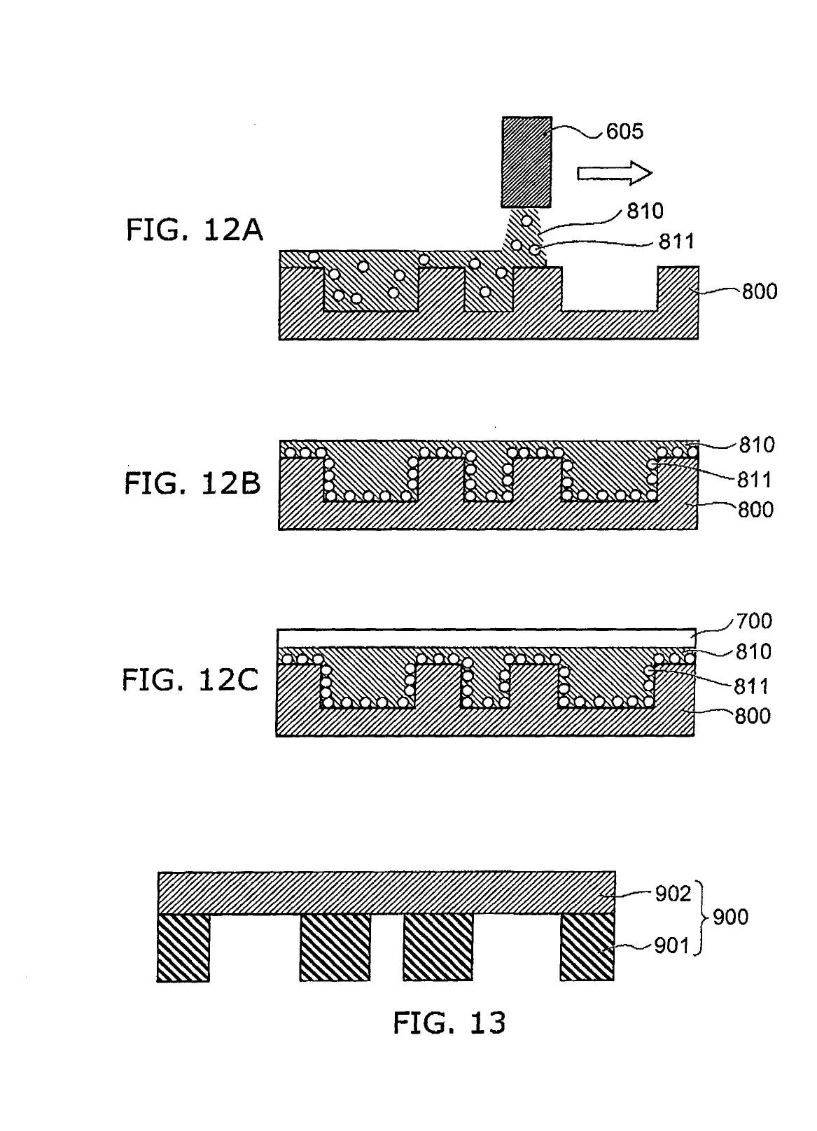

A pattern formation method according to a fifth embodiment will now be described with reference to FIG. 10 to FIG. 12C. FIG. 10 is a schematic view of an imprinting apparatus used to implement the pattern formation method according to this embodiment. FIG. 11 is a flowchart illustrating the pattern formation method according to this embodiment. FIGS. 12A to 12C are cross-sectional views of processes, illustrating the pattern formation method according to this embodiment. In the description of the pattern formation method according to this embodiment, portions of the descriptions and the drawings used in the descriptions of processes similar to those of the pattern formation method according to the first embodiment are omitted; and like reference numerals are used in the drawings.

An imprinting apparatus 600 illustrated in FIG. 10 includes: a chuck for a to-be-processed substrate 604 that fixes a to-be-processed substrate 700 with a major surface (pattern formation surface) of the to-be-processed substrate 700 facing downward; a stage 603 for moving the to-be-processed substrate chuck 604 three dimensionally; a photo-curable agent coating unit 605 that selectively supplies a photo-curable material onto a concavo-convex pattern of a template 800; a template holding unit 608 that holds the template 800 for imprinting such that the concave pattern formation surface faces upward; a first light source 606 (e.g., a UV lamp) that irradiates with light via the template to cure the photo-curable agent; and a second light source 607 that irradiates with light to promote to-be-processed substrate of the cured photo-curable agent. A light source having a wavelength λ, for example, less than 200 nm may be used as the second light source. In this embodiment, a Xe2 excimer lamp with λ=172 nm is used. The template 800 for the imprinting may be a template in which a concavo-convex pattern is made in a transparent quartz substrate by plasma etching and the like. The to-be-processed substrate 700 and the template 800 are set in the apparatus interior when utilizing the apparatus 600 of FIG. 10 and are not included in the configuration of the apparatus 600.

First, a photo-curable agent 810 with a hydrophilizing component 811, e.g., an epoxy resin containing moisture, was prepared as a photo-curable agent 710 used in the pattern formation method according to this embodiment (step S50). Another material, e.g., a material similar to the photo-curable agent 310 used in the second embodiment, may be used as the hydrophilizing component-containing photo-curable agent 810.

Then, as illustrated in FIG. 12A, the template 800 is held by the template holding unit 608 such that the concave pattern surface faces upward; the photo-curable agent coating unit 605 is moved above the pattern surface of the template 800; and the photo-curable agent 810 with a hydrophilizing component is supplied onto the pattern surface of the template 800 (step S51). After supplying the photo-curable agent 810 and filling into the concave pattern of the template 800, the photo-curable agent coating unit 605 is moved upward away from the template 800. The template 800 is made by patterning synthetic quartz.

Continuing as illustrated in FIG. 12B, the hydrophilizing component 811 of the photo-curable agent 810 that filled into the pattern of the template was segregated to the synthetic quartz template interface (step S52).

Then, as illustrated in FIG. 12C, the to-be-processed substrate stage was moved downward; the to-be-processed substrate 700 held with the pattern formation surface facing downward was moved downward; and the pattern formation surface of the to-be-processed substrate 700 was brought into contact with the template 800 via the photo-curable agent 810 (step S53).

The subsequent pattern formation processes are similar to some of the processes of the first embodiment. Namely, as illustrated in steps S14 to S17 and FIGS. 3D to 3F, the light irradiation process to cure the photo-curable agent, the light irradiation process to cause a decomposition reaction of the curable agent to generate a gas by exciting the hydrophilizing component, and the to-be-processed substrate process of the template may be implemented to form the pattern on the to-be-processed substrate. However, the following points differ from the first embodiment. Namely, in the light irradiation process to cure the photo-curable agent and the light irradiation process to cause a decomposition reaction of the curable agent to generate a gas by exciting the hydrophilizing component, the photo-curable agent was irradiated with light via the template not from above the template but from below the template. Also, in the to-be-processed substrate process of the template and the to-be-processed substrate, the to-be-processed substrate stage is moved upward instead of the template to demold the to-be-processed substrate from the template. Further, in the case where a removing process of organic contaminants adhered to the template illustrated in step S17 of the first embodiment is implemented, as described above, the template is irradiated with light not from above the template but from below the template.

Although a transparent material having a constant transmittance such as synthetic quartz is used over the entire portion of the template undergoing light irradiation in the pattern formation methods according to the first embodiment to the fifth embodiment, it is also possible to change the transmittance of a portion of the template or use a light-shielding material in a portion of the template. For example, as in a template 900 illustrated in FIG. 13, it is possible to use a template 900 having different materials in a pattern formation portion 901 and a base portion 902. In the template 900, a material (e.g., a transparent film such as synthetic quartz) having a low absorption coefficient of light having a wavelength of 200 nm or less is used as the material of the base portion 902; and a material (e.g., a light shielding film such as Cr) having a high absorption coefficient with respect to light having a wavelength of 200 nm or less is used as the material of the pattern formation portion 901. In the case where the template 900 is used as the template of the embodiments described above, in the light irradiation process for generating gas at the template interface, the light radiated onto the base portion 902 between the pattern formation portions 901 of the template 900 passes through the base portion 902 to be sufficiently radiated onto the photo-curable agent; while a majority of the light radiated onto the pattern formation portion 901 of the template 900 is absorbed and does not sufficiently reach the photo-curable agent. Accordingly, the photo-curable agent is decomposed to generate a gas at the interface of the base portion 902 between the pattern formation portions 901 of the template and the side surface of the pattern formation portion 901. In such a case as well, the demolding characteristics can be improved by a demolding force occurring to push the photo-curable agent pattern from the template. In the case where the pattern formation portion 901 of the template 900 is semi-transparent with respect to the radiated light, the irradiation amount of light reaching the photo-curable agent monotonously decreases from the surface (the concave surface) of the base portion 902 of the template 900 toward the surface (the protrusion surface) of the pattern formation portion 901. As a result, the gas generation amount at the template interface can be monotonously reduced from the concave surface of the template toward the protrusion surface of the template; and it is also possible to compensate the pressure loss of the template concavity and convexity to push the photo-curable resin pattern. In other words, because the template concavity contacts the photo-curable agent at the side surface when demolding from the template, a demolding force greater than that of the template surface is necessary. However, in the case where a large amount of gas is generated from the photo-curable agent at a constant amount to demold the template concavity, an excessive demolding force acts at the template surface; and there is a risk of undesirably collapsing the photo-curable agent pattern during the demolding. However, as described above, by monotonously reducing the gas generation amount at the template interface from the concave surface toward the protrusion surface of the template, the gas generation amount can be adjusted such that sufficient effects of the to-be-processed substrate force at the template concavity can be obtained while an excessive demolding force does not act at the template surface; and it is possible to suppress pattern defects. MoSi, light shielding films of M0SI, nitride films of MoSi, oxynitride films of MoSi, etc., for example, may be used as materials semi-transparent with respect to such radiated light.

Any substrate used in conventional imprinting technology may be applied as the to-be-processed substrate used in the first embodiment to the fourth embodiment such as substrates for manufacturing semiconductor devices, media substrates of MEMS, hard disks, etc.

As long as the to-be-processed substrate used in the first embodiment to the fifth embodiment is permeable with respect to light radiated from the first light source, it is also possible to irradiate the photo-curable agent with the light of the first light source via the to-be-processed substrate.

Methods discussed in JP-A 2006-186111 (Kokai) may be used as the methods that hydrophilize the photo-curable agent surface in the embodiments described above. Further, it is also possible to use methods discussed in JP-A 2006-32992 (Kokai) or JP-A 2004-363444 (Kokai) to irradiate a photo-curable agent exposed to the atmosphere contains water or an oxygen with light, generate OH radicals or oxygen radicals, decompose the photo-curable agent, and generate a gas.

Hereinabove, according to the pattern formation methods according to various examples recited above, it is possible to generate gas at an interface between a template and a curable agent prior to or during demolding of the template from the photo-curable agent to promote the to-be-processed substrate thereof and improve demolding characteristics.

1. A pattern formation method, comprising:
bringing a template into contact with a photo-curable agent to fill the photo-curable agent into a concave pattern formed on the template;
forming a hydrophilizing component to an interface between the photo-curable agent and a surface of the template;
irradiating the filled photo-curable agent with a first light to cure the photo-curable agent;
irradiating the photo-curable agent including the hydrophilizing component with a second light after irradiating with the first light to cause a reaction of the photo-curable agent at an interface of the template; and
demolding the template from the photo-curable agent to form a photo-curable agent pattern.

2. The method according to claim 1, wherein any of water, butanol, heptanol, hexanol, or octanol is used as the hydrophilizing component.

3. The method according to claim 1, wherein irradiation with the second light is performed to cause a decomposition reaction of the photo-curable agent at the interface of the template.

4. The method according to claim 1, comprising
supplying a hydrophilizing component to a surface of the photo-curable agent to form a hydrophilic layer on the surface of the photo-curable agent and bringing the hydrophilic layer of the surface of the photo-curable agent into contact with a concave pattern surface of the template
prior to the filling of the photo-curable agent into the concave pattern of the template.

5. The method according to claim 4, wherein a vapor or a mist of the hydrophilic component is supplied to the photo-curable agent surface.

6. The method according to claim 1, wherein
the bringing of the template into contact with the photo-curable agent includes bringing the photo-curable agent containing the hydrophilizing component into contact with a concave pattern surface of the template.

7. The method according to claim 1, comprising
forming a hydrophilic layer on a surface of the photo-curable agent by irradiating the photo-curable agent with a light via a atmosphere with a hydrophilizing component while the photo-curable agent being exposed to the atmosphere with hydrophilizing component
prior to the filling the photo-curable agent into the concave pattern of the template.

8. The method according to claim 7, wherein the photo-curable agent is irradiated with the light to leave a portion of the photo-curable agent other than the hydrophilic layer in an uncured state.

9. The method according to claim 7, wherein any of a moisture-containing atmosphere, an oxygen-containing atmosphere, or an ozone-containing atmosphere is used as the hydrophilic component-containing atmosphere.

10. The method according to claim 9, wherein the irradiated light has a wavelength of not more than 200 nm.

11. The method according to claim 7, wherein any of a hydrogen peroxide-containing atmosphere, an ozone-containing atmosphere, or an atmosphere having a hydrogen peroxide-containing atmosphere or an ozone-containing atmosphere added to at least one selected from a moisture-containing atmosphere and an oxygen-containing atmosphere is used as the hydrophilizing component-containing atmosphere.

12. The method according to claim 11, wherein the irradiated light has a wavelength of not more than 300 nm.

13. The method according to claim 1, comprising
forming a hydrophilic layer on a surface of the photo-curable agent by exposing the photo-curable agent to an oxidative component-containing atmosphere containing an oxidative component to oxidize the photo-curable agent
prior to the filling of the photo-curable agent into the concave pattern of the template.

14. The method according to claim 13, wherein any of an ozone-containing atmosphere, a hydrogen peroxide-containing atmosphere, or a nitrogen peroxide-containing atmosphere is used as the oxidative component-containing atmosphere.

15. The method according to claim 1, wherein the template includes a pattern formation portion and a base portion, the base portion having an optical transmittance with respect to the second light different from an optical transmittance of the pattern formation portion with respect to the second light.
